(19) United States
(12) Patent Application Publication
(10) Pub. No.: US 2013/0323930 A1
(43) Pub. Date: Dec. 5, 2013

(54) Selective Capping of Metal Interconnect Lines during Air Gap Formation

(71) Applicants: Kaushik Chattopadhyay, San Jose, CA (US); George A. Antonelli, Portland, OR (US); Pramod Subramonium, Beaverton, OR (US); Mandyam Sriram, Beaverton, OR (US); Tighe A. Spurlin, Portland, OR (US)

(72) Inventors: Kaushik Chattopadhyay, San Jose, CA (US); George A. Antonelli, Portland, OR (US); Pramod Subramonium, Beaverton, OR (US); Mandyam Sriram, Beaverton, OR (US); Tighe A. Spurlin, Portland, OR (US)

(21) Appl. No.: 13/482,786

(22) Filed: May 29, 2012

(51) Int. Cl. H01L 21/02

(52) U.S. Cl. CPC H01L 21/02107
USPC 438/703; 156/345.26

(57) ABSTRACT

Provided are methods and systems for forming air gaps in an interconnect layer between adjacent conductive lines. Protective layers may be selectively formed on exposed surfaces of the conductive lines, while structures in between the lines may remain unprotected. These structures may be made from a sacrificial material that is later removed to form voids. In certain embodiments, the structures are covered with a permeable non-protective layer that allows etchants and etching products to pass through during removal. When a work piece having a selectively formed protective layer is exposed to gas or liquid etchants, these etchants remove the sacrificial material without etching or otherwise impacting the metal lines. Voids formed in between these lines may be then partially filled with a dielectric material to seal the voids and/or protect sides of the metal lines. Additional interconnect layers may be formed above the processed layer containing air gaps.

### BACKGROUND

Damascene processing is a method for forming metal lines on integrated circuits. It involves formation of metal interconnect lines in trenches and vias formed within a dielectric layer. Damascene processing generally employs fewer processing steps than other methods and offers a higher yield. It is also particularly well-suited to metals, such as copper, that cannot be readily patterned by plasma etching.

In a typical Damascene process flow, metal is deposited onto a patterned dielectric to fill the vias and trenches formed within this dielectric. The resulting metallization layer may be formed either directly on a layer carrying active devices or on a lower lying metallization layer. A thin layer of a dielectric diffusion barrier material, such as silicon carbide or silicon nitride, is deposited between adjacent metallization layers and/or between metal interconnect lines and dielectric to prevent diffusion of metal into the dielectric. In a typical integrated circuit, several metallization layers may be deposited on top of each other forming a stack. Conducting paths of one metallization layer may be connected to conducting paths of an adjacent layer by a series of Damascene interconnects.

Fabrication of these interconnects presents several challenges, which become more and more significant as the dimensions of integrated circuit features continue to shrink. At the 90 nm technology node and at more advanced nodes, maintaining dielectric properties between adjacent metal interconnect lines becomes a challenge.

### SUMMARY

Provided are methods and systems for forming air gaps in an interconnect layer between adjacent conductive lines. Protective layers may be selectively formed on exposed surfaces of the conductive lines, while structures in between the lines may remain unprotected. In some embodiments, the protective layers are formed over the entire substrate, including both exposed surfaces of conductive lines and surfaces of structures between the lines. These structures may be made from a sacrificial material that is later removed to form voids (sometimes referred to as “air gaps”. In certain embodiments, the structures are covered with a permeable non-protective layer that allows etchants and etching products to pass through during removal. When a work piece having a selectively formed protective layer is exposed to gas or liquid etchants, these etchants remove the sacrificial material without etching or otherwise impacting the metal lines. Voids formed in between these lines may be then partially filled with a dielectric material to seal the voids and/or protect sides of the metal lines. Additional interconnect layers may be formed above the processed layer containing air gaps.

Certain aspects of the disclosure concern methods of creating an air gap in an interconnect layer. One such method may be characterized by the following operations: (a) receiving a work piece having an interconnect layer with exposed metal interconnect lines and a sacrificial material around a portion of the metal interconnect lines; (b) selectively forming a protective layer on the exposed surfaces of the metal interconnect lines; and (c) exposing the work piece to an etchant to selectively remove the sacrificial material from the interconnect layer, while the protective layer protects the surfaces of the metal interconnect lines from substantial etching. Exposure to the etchant defines at least a portion of the air gap. The protective layer is formed from one or more precursor gases in a reaction chamber.

In certain embodiments, the sacrificial material contains a silicon oxide. In some embodiments, the metal lines contain copper.

Prior to selectively forming the protective layer, the work piece may be pre-cleaned to remove contaminants and/or oxide from at least the exposed surfaces of the metal interconnect lines. In one example, the pre-cleaning is performed using a plasma treatment.

Exposing the work piece to the etchant may be conducted under conditions that expose, at least partially, sidewalls of the metal interconnect lines. In some embodiments, the etchant includes ammonium fluoride or hydrofluoric acid. In certain embodiments, the etchant includes chlorine, dichlorodifluoromethane, trifluoromethane, tetrafluoromethane, sulfur hexafluoride, or nitrogen trifluoride.

In certain embodiments, the method includes an additional operation of forming a semipermeable layer over the interconnect layer. In such cases, exposing the work piece to the etchant removes the sacrificial material under the semipermeable layer and thereby forms the air gaps. Typically, the semipermeable layer extends over the protective layer. In certain embodiments, the semipermeable layer includes a polymer.

The method may include an additional operation of forming a dielectric layer over the exposed surfaces of the metal interconnect lines. This additional operation may form a closed air gap in the interconnect layer. Forming the dielectric layer over the surfaces of the metal interconnect lines may involve performing non-conformal chemical vapor deposition (CVD). In some embodiments, the air gaps occupy at least about 25% of the interconnect layer.

In certain embodiments, a precursor gas used for selectively forming the protective layer is silane, germane, diborane, trimethylaluminum, tetrakis(dimethylamino) titanium, or tetrakis(diethylamino)titanium. Forming the protective layer may be performed under the following conditions: flowing the one or more precursor gases at a flow rate from about 0.001 sccm to about 10,000 sccm, maintaining a temperature of the work piece ranging from about 20° C. to about 500° C., and maintaining a pressure range of about 10 mTorr to about 100 Torr. In some embodiments, the protective layer has a thickness of at least about 100 Å.

In various embodiments, the method is performed in a multi-station or multi-chamber apparatus. In some implementations, at least two operations are performed in two different stations or chambers of the apparatus.

Another aspect of the disclosure concerns a processing system for creating an air gap in an interconnect layer. In certain embodiments, the processing system includes the following features: (a) a reaction chamber for receiving a work piece having an interconnect layer including metal interconnect lines having exposed surfaces and a sacrificial material around a portion of the metal interconnect lines not including the exposed surfaces of the metal interconnect lines; and (b) a system controller for executing a set of instructions for implementing some or all operations described in one or more of the methods presented herein. In one example, the instructions are for executing the following operations: (i) introducing one or more precursor gases in the reaction chamber to selectively form a protective layer on the exposed surfaces of the metal interconnect lines; and (ii) exposing the work piece to an etchant to selectively remove the sacrificial material from the interconnect layer. As with the methods described above, the protective layer protects the surfaces of the metal interconnect lines from substantial etching while the etchant defines at least a portion of the air gap. In some examples, the reaction chamber is a multistation chamber.

These and other features and embodiments are described below with reference to the figures.

### BRIEF DESCRIPTION OF THE DRAWINGS

FIGS. 1A-1G illustrate cross sectional depictions of device structures created on a work piece at various stages of a dual Damascene fabrication process, in accordance with certain embodiments.

FIG. 2 is a process flowchart corresponding to a method of creating an air gap in an interconnect layer, in accordance with certain embodiments.

FIGS. 3 and 4 illustrate SEM images of two samples after wet etching operation in hydrofluoric acid solutions.

FIG. 5 provides a simple block diagram depicting various reactor components arranged for performing various operations of creating an air gap in an interconnect layer, in accordance with certain embodiments.

FIG. 6 is a schematic representation of a multi-station apparatus capable of running different processes concurrently in the same chamber environment, in accordance with certain embodiments.

FIG. 7 is a schematic representation of a multi-chamber apparatus capable of running different processes concurrently in different chamber environments, in accordance with certain embodiments.

### DETAILED DESCRIPTION OF EXAMPLE EMBODIMENTS

In the following description, numerous specific details are set forth in order to provide a thorough understanding of the presented concepts. The presented concepts may be practiced without some or all of these specific details. In other instances, well known process operations have not been described in detail so as to not unnecessarily obscure the described concepts. While some concepts will be described in conjunction with the specific embodiments, it will be understood that these embodiments are not intended to be limiting.

### Introduction

The integration of low-k materials into copper dual-damascene structures may be difficult particularly for very small line sizes. Introducing air gap in between metal interconnect lines improves interline capacitance characteristics by reducing effective k-values. Previous attempts have been made to reduce the effective dielectric constant of the interline regions of metallization layers by introducing pores into standard dielectric base materials located between the metal lines. Air gaps may be viewed as a logical extension of the porous dielectric technology. Air gaps may be introduced into an integrated circuit layer during its fabrication by partial or complete removal of sacrificial materials from areas between metal interconnect lines. Removal usually involves etching using aggressive etchants or other like techniques that may compromise metal lines, if these lines remain unprotected. For example, exposed surfaces of these lines may corrode causing increases in resistance (e.g., due to scattering effects), poor adhesion to additional layers in the overall structures, poor electromigration, and other problems.

Provided methods and systems allow creation of air gaps while protecting metal interconnect lines during removal of the sacrificial material and sometimes other operations as well. In certain embodiments, protective layers are selectively formed on exposed surfaces of the conductive lines, while structures in between the lines may remain unprotected. When a work piece having a selectively formed protective layer is exposed to gas, plasma, and/or liquid etchants, these etchants remove the sacrificial material without substantially etching or otherwise impacting the metal lines. The sacrificial material may be either an organic polymer or oxide.

In various embodiments, the sacrificial material is simply removed to leave recessed regions around the metal lines. In certain embodiments, removal of sacrificial material is performed through a permeable non-protective layer. This layer may be selectively formed over sacrificial material structures in addition to the protective layer formed over the metal interconnect lines. Different approaches exist to remove the sacrificial material through a permeable non-protective layer. For example, a thermal degradable polymer may be used as the sacrificial material. This polymer may be decomposed by heat, sometimes in a combination with UV exposure. The gaseous decomposition products may escape through the permeable layer. In another example, the sacrificial material may be removed by selective wet or dry etching, in which both etchants and products pass through the permeable layer. For example, silicon dioxide may be used as a sacrificial material in a combination with an organic polymer as a permeable layer. Other examples of permeable layers include porous silicon carbide (SiC), porous silicon carbide nitride (SiCN), and combinations thereof. Air gaps may be formed in this stack after full completion of the stack, and the sacrificial silicon dioxide may be selectively etched in a hydrofluoric acid solution through the permeable layer.

In certain embodiments, voids formed in between the metal lines are partially filled with a dielectric material. Deposition of this material may be performed in a non-conformal manner to seal the voids while retain some air gap in between the metal interconnect lines. For example, a non-conformal PECVD deposition may be used followed by another planarization operation.

Creation of air gap substantially reduces the effective k-values. It has been shown that k-values as low as 1.8 may be achieved using this approach. These values can be tuned, in certain embodiments, by controlled deposition of the non-conformal dielectric material into the voids. The stack may utilize specific dielectric materials (in particular, dense dielectric materials) and still meet both thermal and mechanical requirements for packaging, such as in low density areas or pads. To the contrary, porous inter-metal fillers, which are sometimes presented as alternatives to air gap approaches, generally have poor mechanical properties. It should be noted that porous dielectric materials may be used as sacrificial material structures and/or as backfilled dielectric partially filling created voids in the processed work piece.

Formation of protective layers and air gaps in an interconnect layer will now be illustrated in the context of a copper dual Damascene processing. It will be understood that methods disclosed herein can be used in other structured and processing methods, including single Damascene processing. Furthermore, it will be understood that these approaches can be applied to a variety of metals beyond copper. For example, these methods can be applied to gold and/or silver-containing interconnects.

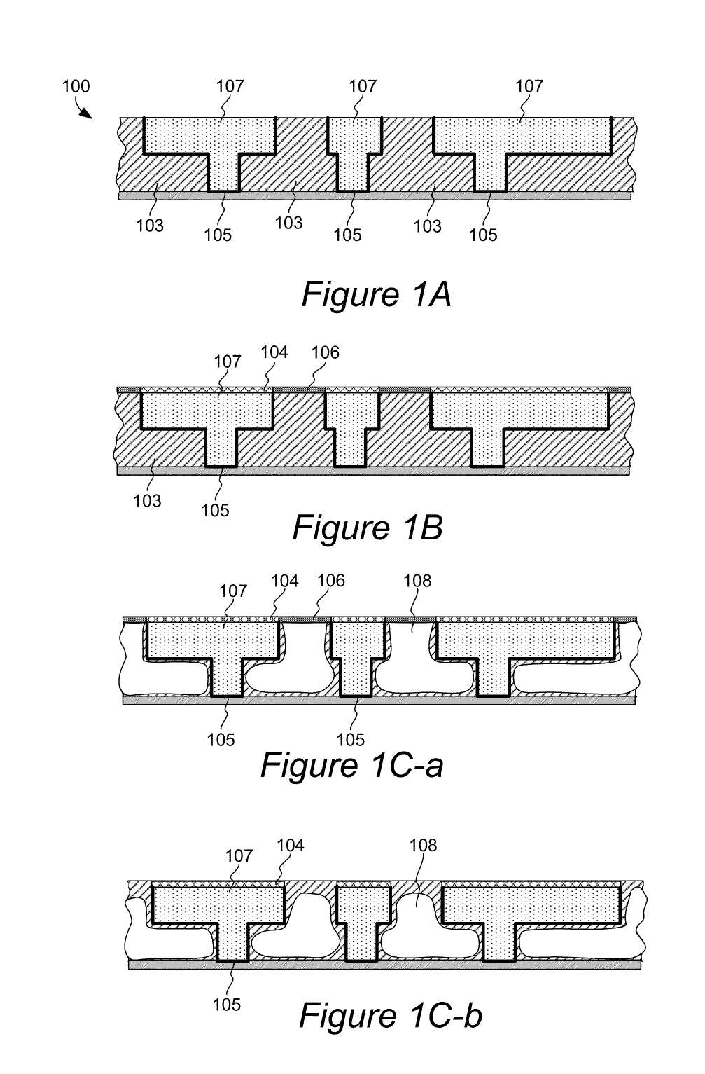

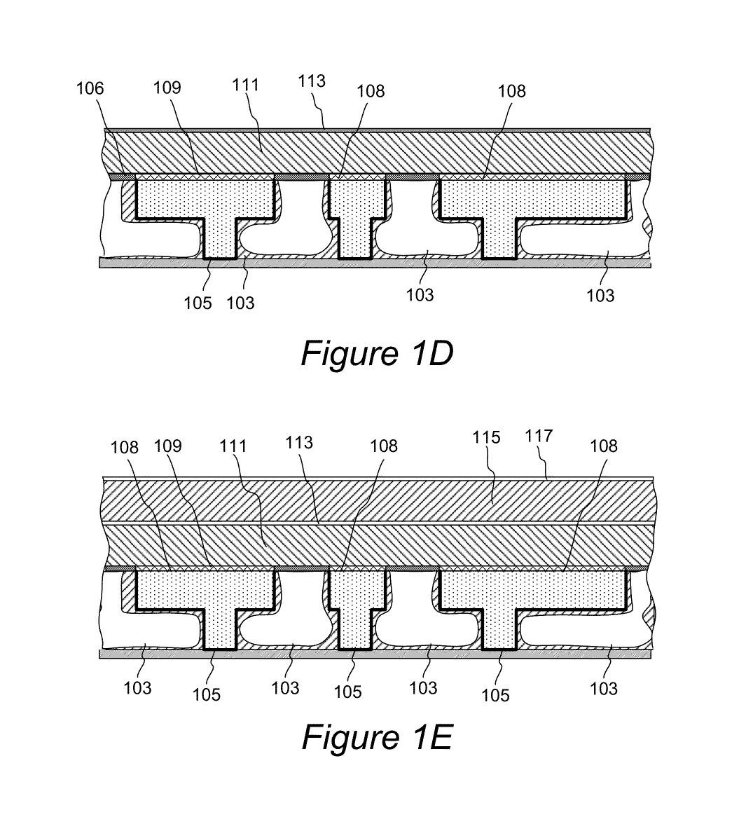

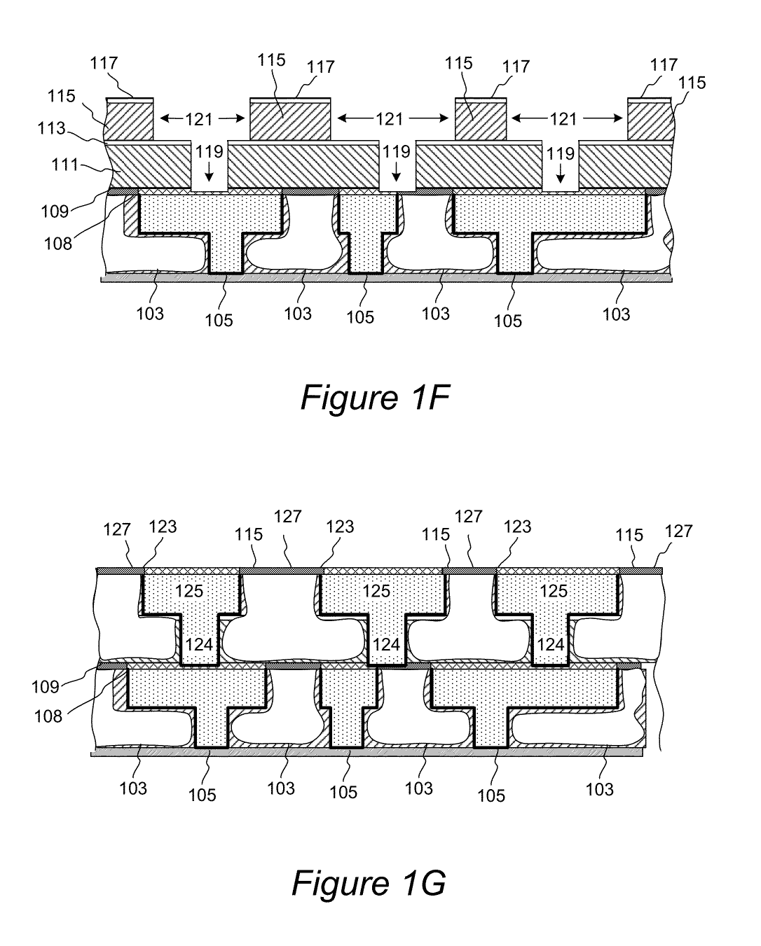

Presented in FIGS. 1A-1G are cross sectional depictions of device structures created on a work piece at various stages of a dual Damascene fabrication process, in accordance with certain embodiments. A cross sectional depiction of a completed structure having air gaps on different level of the stack is shown in FIG. 1G. A “semiconductor substrate” or a “work piece” used in this application is not limited to the semiconductor portions of an integrated circuit device, but is broadly defined as a semiconductor containing substrate. Referring to FIG. 1A, an example of a partially fabricated integrated circuit structure or work piece 100 used for dual Damascene fabrication is illustrated.

A layer 103 illustrated in FIG. 1A is a layer of sacrificial material that is at least partially removed during later operations. A variety of sacrificial materials for air gap applications are known in the art. Some examples of sacrificial materials include silicon dioxide, amorphous carbon, and polymers and other organic materials. In certain embodiments, silicon dioxide may be doped with fluorine, nitrogen or carbon. Various porous structures may be used as well.

Layer 103 is etched with line paths (trenches and vias) in which a partially conductive metal diffusion barrier 105 is deposited, followed by inlaying with metal interconnect lines and/or vias 107. For convenience, metal lines and vias will be referred to collectively as “lines” herein. Because copper or other mobile conductive material provides the conductive paths of the work piece, the underlying silicon devices and dielectric layers proximate to metal lines must be protected from metal ions (e.g., Cu ions) that might otherwise diffuse or drift into the silicon or inter-layer dielectric and result in degradation of their properties. Several types of metal diffusion barriers may be used in order to protect the dielectric layers of the IC device. These types may be divided into partially conductive metal-containing layers such as barrier 105 and dielectric barrier layers which are further described below. Suitable materials for partially conductive diffusion barrier 105 include materials, such as tantalum, tantalum nitride, titanium, titanium nitride and the like. These are typically deposited onto a dielectric layer having vias and trenches by a PVD, CVD or an ALD method. Diffusion barrier 105 also provides protection to side walls of metal interconnect lines 107 during removal of sacrificial material from layer 103. Some diffusion barrier layer materials may easily oxidize. To protect these materials, the walls and voids may be sealed from the environment after completion of the processing as further explained below.

Metal interconnect lines 107 may include copper and/or other conductive materials. These lines can be formed by a number of techniques, including PVD, electroplating, electroless deposition, CVD, etc. In some implementations, a copper fill includes depositing a thin seed layer of copper by PVD and subsequently depositing bulk copper fill by electroplating. Since copper is typically deposited with overburden residing in the field region, a chemical mechanical polishing (CMP) operation is needed to remove the overburden and to obtain a planarized structure 100.

Next, referring to FIG. 1B, after the work piece 100 has been completed, the surface of the work piece 100 is optionally pre-cleaned to remove contaminants and metal oxide. For example, a glacial acetic acid may be used for this purpose. In certain embodiments, removal of contaminants and metal oxide allows for more effective and selective formation of protective layers 104 and better adhesion of protective layers 104 to metal lines 107 particularly when corrosion inhibitors are used to form protective layers 104. For example, copper lines tend to quickly form copper oxides upon completion of CMP. Glacial acetic acid may be used to treat the surface of such work pieces to remove copper oxide prior to introducing corrosion inhibitors or other precursors used to form protective layer 104.

After the pre-clean, a protective layer or layers 104 are selectively formed on the top exposed surfaces of metal lines 107. Protective layers 104 may extend slightly past the top surfaces of metal lines 107 to protect the corners of the metal lines 107, i.e., the interface between protective layers 104 and diffusion barrier 105 provided on the side of the metal lines 107. This extension of protective layers 104 formed in accordance with described techniques should be contrasted with cobalt capping techniques where cobalt caps are selectively formed on top surfaces of copper lines to protect these lines from etchant. These cobalt caps, which may be formed by electroless or selective chemical vapor deposition sometimes have a surface wetting issue at the interface between the metal barrier, e.g., tantalum nitride/tantalum, and copper surfaces due to the nature of the selective deposition process. The demarcation between these two metallurgies is a weak point for the cap and may be a site for the initiation of corrosion.

Protective layer 104 may be in the form of a film, which may have a range of acceptable thicknesses. In some embodiments, the film is substantially thicker than a monolayer typically used in protective self-aligned buffer (PSAB) approaches used to address electromigration and/or adhesion issues. In certain embodiments, the protective layer has a thickness of at least about 100 Å or, more specifically, at least about 500 Å. Examples of protective layers will be described in more detail below. In the context of these examples, it should be understood that electrical properties of the protective layer can be tuned to desirable levels by plasma post treatments (oxidizing post treatments in particular).

In certain embodiments, protective layer 104 is formed by reaction of metal lines 107 with one or more precursors provided over the surface of the work piece either as a gas or as a liquid. The sacrificial material in between metal lines 107 may also react with these precursors. However, because this sacrificial material does not include metals the reaction products are different than the composition of protective layer 104. These reaction products may form a permeable non-protective layer in certain embodiments. In other embodiments, the sacrificial material does not react with one or more precursors provided over the surface of the work piece to form protective layer 104. As such, protective layer is selectively formed over metal lines 107.

In other embodiments, protective layer 104 is formed by adsorption of one or more materials on exposed surfaces of metal lines 107. In these embodiments, there may be no chemical transformation of any metal in metal lines. For example, protective layer 104 may be formed by corrosion inhibitors provided, for example, in a solution. Some examples of such corrosion inhibitors include 2-aminopyrimidine (AP), 2-amino-5-mercapto-1,3,4-thiadiazole (AMT), benzotriazole (BTA), 5,6-dimethylbenzimidazole (DB), 2-mercaptobenzimidazole (MBI), 2-mercaptobenzoxazole (MBO), 2-mercaptopyrimidine (MP) and 2-mercaptobenzothiazole (MBT), and the like. In this example, protective layer 104 may be formed prior to etching of sacrificial materials or during the etching. For example, corrosion inhibitors may be provided right in the etching solution. These corrosions inhibitors are later removed from the copper surface prior to formation of additional layers over the metal liners. The inhibitors can be removed by plasma treatment or during deposition of the non-conformal deposition to seal the voids.

In the adsorption embodiments, the one or more chemicals forming protective layer over metal lines 107 may not adsorb over the sacrificial material. Sometimes other chemical may adsorb over the sacrificial material and may form a permeable non-protective layer.

Typically, the permeable layers 106 are formed before or after protective layers 104 and may overlap and form a stack with these layers as further explained below. Typically, the permeable layers 106 and the protective 104 are different materials. In certain embodiments, no layers are formed over the sacrificial material prior to etching or a layer formed in these regions is removed by etchant during etchant or by other process prior to etching. This type of layer may be referred to as a removable layer. The permeable layers 106 may remain as a part of the final integrated circuit and may, for example, support additional layers of the stack. Alternatively, the permeable layers 106 may be removed during or after the etching operation.

In certain alternative embodiments, formation of protective layers 104 coincides with formation of permeable layers 106 over the sacrificial material as explained above (e.g., by forming different reaction products and/or by adsorbing different materials on the surface of the sacrificial material). The permeable layers 106 allow for etchant to penetrate through and reach the sacrificial material and for reaction products to escape. The types of materials that could serve the dual function of permeable layer and protective layer may be selected from the general class of PECVD Si—C—N—H dielectric barrier type materials which have high porosity (low density) resulting from, e.g., organic end groups. These materials have been made intentionally non-hermetic. There is a balance to be maintained between structural integrity, porosity, and hydrophobicity.

Once, protective layers 104 are selectively formed on the top surfaces of metal lines 107, the process may continue with at least partial removal of the sacrificial material. Etching and other techniques further described below may be used for this purpose. In certain embodiments, some inter-metal dielectric remains between metal lines 107 as, for example, shown in FIG. 1C-a. In other embodiments, substantially all inter-metal dielectric is removed from layer 103.

In certain embodiments, a dielectric material may be deposited onto the metal lines 107 created during removal of the sacrificial material to seal the voids and form the air gaps. Because the deposition is non-conformal, it may partially fill the void between metal lines 107. This newly deposited dielectric material may have the same composition as the sacrificial material (e.g., both are silicon dioxide) or may have a different composition. In one example, silicon dioxide doped with fluorine or carbon may be used to seal the voids. Various porous structures may be used as well. Generally, to minimize the dielectric constant of the inter-metal dielectric stack, materials with a k value of less than about 3.5, generally less than about 3.0 and often as low as about 2.8 are employed as inter layer dielectrics. However, because air gaps are later formed in inter-metal dielectric, materials with high k values may be used as well.

In certain embodiments, a new dielectric material is deposited through permeable layer 106 and may not itself seal the void. A resulting structure is shown in FIG. 1C-a. In other embodiments, (e.g., when a permeable layer is not present), a new dielectric material is deposited in a non-conformal manner to seal the void. The new dielectric material creates an air gap and provides a surface for depositing additional layers in the stack. A resulting structure is shown in FIG. 1C-b (although for convenience the non-conformal structure is not depicted). In either case, spacing between adjacent metal lines includes air gaps 108. In various embodiments, the non-conformal material is a PECVD SiO₂, or a different class of PECVD material such as an organosilicate low-k material, or even a spin-on material.

In certain embodiments, an etch layer is deposited over layers 104 and 106 prior to further processing. The etch layer and/or other components may be deposited over protective layers 104 and/or non-protective layers 106. In certain embodiments, protective layers 104 is removed prior to further processing.

Other layers may be deposited at the interface between Damascene layers, such as diffusion barrier layers and etch stop layers. Silicon nitride and/or nitrogen-doped silicon carbide (NDC) may be used for these applications. Other materials include carbon-rich silicon carbide materials, such as those described in commonly assigned U.S. patent application Ser. No. 10/869,474 by Yu et al., filed on Jun. 15, 2004; boron-doped silicon carbide materials described in U.S. patent application Ser. No. 10/915,117 by Yu et al., filed on Aug. 9, 2004; in U.S. patent application Ser. No. 11/373,847 by Yu et al. filed on Mar. 8, 2006; and oxygen-doped silicon carbide materials, e.g., described in U.S. Pat. No. 6,855,645 by Tang et al. issued on Feb. 15, 2005. Further, bi-layer and tri-layer configurations can be employed for the diffusion barrier 109. Examples of suitable bi-layer and tri-layer barrier films are described, for example, in the previously cited U.S. patent application Ser. No. 10/869,474; Ser. No. 10/915,117; and in U.S. patent application Ser. No. 11/710,652 by Yu et al., filed on Feb. 22, 2007. All patent applications mentioned in this paragraph are hereby incorporated by reference for purposes of describing these layers.

Referring to FIG. 1D, another dielectric layer 111 of a dual Damascene dielectric structure is deposited over layer 103. This deposition may be followed by deposition of an etch stop film 113 by a PECVD method on the first dielectric layer 111. The dielectric layer 111 is typically composed of low-k dielectric materials, such as those listed for layer 103 (e.g., the sacrificial material and/or new dielectric material added after etching to partially fill the voids). Note that materials in layers 111 and 103 need not necessarily have identical composition. Similarly, etch stop layer 113 may or may not have an identical composition to layer 109.

The process follows, as depicted in FIG. 1E, where a second dielectric layer 115 of the dual Damascene dielectric structure is deposited in a similar manner to the first dielectric layer 111, onto an etch-stop film 113. Deposition of an antireflective layer (not shown) and a CMP stop film 117 follows. Second dielectric layer 115 may contain a low-k dielectric material such as those described above for layers 103 and 111. A CMP stop film 117 serves to protect the delicate dielectric material of inter-metal dielectric (IMD) layer 115 during subsequent CMP operations. The CMP stop layer may be subject to similar integration requirements as a diffusion barrier and etch stop films 109 and 113, and can similarly be composed of materials described for layer 109.

The dual Damascene process continues, as depicted in FIGS. 1F-1G, with etching of vias 119 and trenches 121 in the first and second dielectric layers. Standard lithography techniques are used to etch such trench and via patterns. A trench-first and/or via-first method may be used. These newly formed vias and trenches are, as described above, coated with a metal diffusion barrier 123, which may contain barrier materials, such as tantalum, tantalum nitride or other materials that effectively block diffusion of copper atoms into the dielectric layers. In certain embodiments, diffusion barrier layers 113 and 123 are permeable to or removable by etchants used for etching layers 111 and 115.

After the diffusion barrier 123 has been deposited, a seed layer of copper, for example, may be deposited (e.g., by a PVD process) to enable subsequent electro-filling of the features with copper inlay. Metal (e.g., copper) may be then filled by electrofill and excess metal deposited in the field is removed in a CMP operation, performed such that CMP stops at the CMP stop film 117.

The process of depositing protective layers over metal lines 125 may be repeated. Likewise air gaps may be formed in between adjacent metal lines as shown in FIG. 1G. In some approaches, air gaps in the top layers (111 and 115) are merged with air gaps in the bottom layer (103) and form a continuous air gap extending through multiple layers. FIG. 1G shows the completed dual Damascene process with air gaps in the interlayer dielectric, in which conductive routes 124 and 125 are inlayed (seed layer not depicted) into the via and trench surfaces. Specifically, this figure illustrates three Damascene interconnects, in which metal layer 107 is connected with metal layer 124 of an overlying metallization layer.

In addition to protecting metal lines during etching, protective layers have additional functions, such as serving as a barrier layer. First, the protective layer protects the metal layer 107 from inadvertent oxidation. Without the protective layer, metal surface (e.g., copper) could be oxidized to copper oxide during exposure to oxygen or moisture in the course of device fabrication or during end use of the device. Formation of metal oxide is typically highly undesirable since it increases resistance of interconnects, and, further, commonly leads to formation of voids in the interconnect structure. Formation of voids in the metal lines is detrimental to integrated devices and should be avoided when possible.

Next, in some embodiments, protective layers, when retained as a part of integrated circuits, diminishes electromigration at the interface between metal lines, and a dielectric diffusion barrier. It has been found that this interface is the most likely point of failure during line current stress. Whereas the electromigration resistance of copper is high enough to sustain the wear-out in normally designed metal lines, defect-induced electromigration failures have been observed at the interface between the copper and dielectric barrier layer. For instance, wherein copper oxides or hydroxides have been undesirably formed at such interfaces, voids will be formed in the copper layer, which increase the risk of electromigration in interconnects. Understandably, current density in these regions is quite high during actual use, thereby causing defect-induced electromigration failure of such interconnects. Remaining protective layers protect metal layers from formation of defects, and thereby improve electromigration properties of interconnects.

Further, protective layers can provide improved adhesion between metal layers and diffusion barrier layers. Adhesion of metal to a barrier layer is an important characteristic of a copper interconnect. Poor adhesion may result in insufficient hermeticity of diffusion barrier layer and can lead to delamination of the diffusion barrier layer from an underlying metallization layer. Ultimately, such delamination may lead to failure of an interconnect. Generally, as the dielectric constant of diffusion barrier material decreases, its adhesion to an underlying metal layer becomes weaker. This is especially true for diffusion barrier materials having high content of organic residues, such as alkyl groups, carbon-carbon bonds, etc., which generally hinder adherence to metal layers. Further, referring to barrier film stress characteristics, many barrier materials having low dielectric constants, form films that are not sufficiently compressive to effect good adhesion to metal layers. With these challenges in mind, it is often desirable to use protective layers to strengthen adhesion between metal layers and diffusion barrier layers with low dielectric constant.

A protective layer may have a multi-layer structure. Specifically, a protective layer may have two or more sub-layers, which may have a distinct or gradually changing composition. For example, a protective layer may have a bottom sub-layer predominantly composed of CuxSiy and a top sub-layer predominantly composed of SixNy. In some embodiments, concentrations of CuxSiy and SixNy within a protective layer are gradual. Such sub-layers may be formed by transforming the top portion of the first-formed protective layer. For example, the top portion of a protective layer may be modified by a transformation, effected by chemical treatment, plasma treatment, thermal treatment, and various combinations of these treatments.

In some embodiments, the first-formed protective layer (containing, e.g., CuxSiy) is entirely transformed to a modified protective layer, without forming sublayers of material. A particular chemistry and amount of such modification is tailored to a particular application for a protective layer, for example, for specific etchant used during air-gap formation. In some embodiments, chemical modification of the first-formed protective layer may be necessary to control the thickness of protective layer. Further, in some embodiments, it may be advantageous to transform the first-formed protective layer or its top portion to a material that provides optimal adhesion with a dielectric diffusion barrier. Some of such materials include silicon nitride, silicon carbide, hydrogen-doped carbon, and their various doped modifications.

In certain embodiments, a protective layer has a graded composition. This type of a protective layer may be viewed as an alloy of, for example, copper metal with protective material, or as a layer of copper impregnated with protective material at an interface with a dielectric diffusion barrier layer. The resulting material is particularly advantageous for improvement of adhesion between metal and dielectric layers, as gradual change in material properties leads to good binding between the two layers. While in some embodiments, protective layers are graded, in other embodiments protective layers may be distinct rather than blended into the underlying metal layers, and may have an abrupt boundary with the metal layer.

In certain embodiments, a protective layer contains materials having relatively low conductivity, and, therefore, their presence in the IC circuit may increase resistance of interconnects. Of course, in certain embodiments, protective layers may be removed from the surface of the copper lines after completing the air gap formation. However, in certain embodiments, protective layers are retained for reasons explained above. In these embodiments, increase in resistance may be undesirable, and thicknesses of protective layers may need to be carefully controlled to avoid unacceptable increases in resistance. Inadvertent formation of unnecessarily thick protective layers may increase interconnect resistance to levels that may not be acceptable in the industry. The challenges of preparing thin protective layers become more pronounced as the dimensions of features in IC devices continue to decrease. It is, for example, difficult to control protective layer thickness, and hence, interconnect resistance in metal lines that are only about 1000 Å deep. Methods of forming controlled amounts of protective materials are provided herein. These methods can be applied to various integrated circuits having a wide range of feature sizes, but may find particular use for IC device fabrication at 90 nm technology node and at more advanced nodes. For example, these methods may be particularly useful for fabricating devices, in which thickness of a single metallization layer does not exceed 1000 Å

### Protective Layer Formation

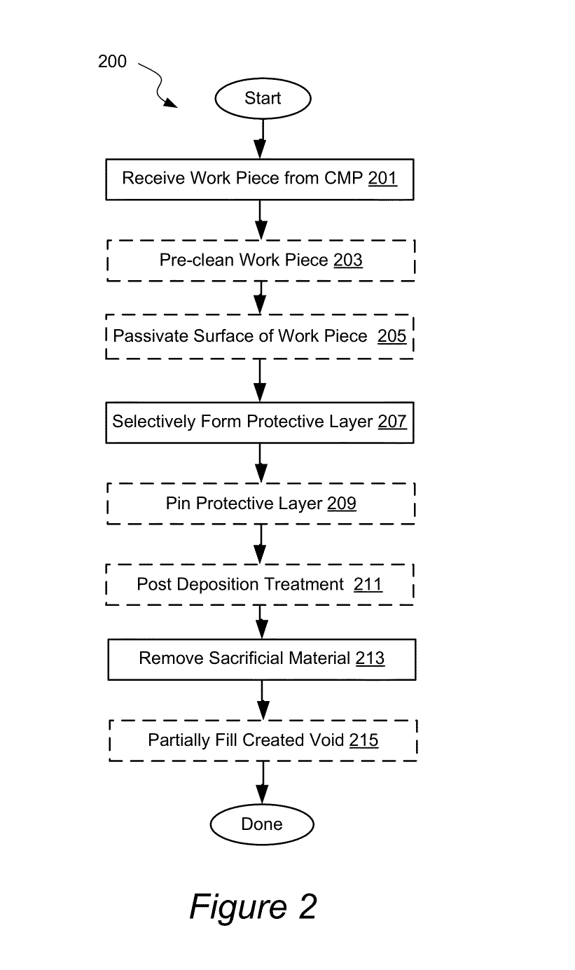

Referring to FIG. 2, the process starts by receiving a work piece having an interconnect layer including interconnect metal lines and sacrificial material surrounding a portion of the metal interconnect lines, as shown in process block 201. The work piece is provided after the vias and trenches have been filled with metal and excess metal has been removed by CMP. Examples of such work pieces are illustrated in FIG. 1A, vias and trenches formed in sacrificial material 103 are lined with a diffusion barrier 105 and are filled with metal fills 107. The work piece is planarized by CMP prior to formation of the protective layer. metal interconnect lines having exposed surfaces

In certain embodiments, the entire process shown in FIG. 2 is performed in a vacuum environment, without breaking the vacuum or exposing the partially fabricated device to an ambient atmosphere during or between the operations shown in FIG. 2. In some embodiments, the entire process depicted in FIG. 2 is performed in one apparatus such as a multi-station vacuum process chamber. Further, in some embodiments, the entire process depicted in FIG. 2 can be performed at one station, two stations, three stations, or more in a multi-station apparatus. In certain embodiments, plasma post-treatment operations further described below and/or etching operation to form air gaps in the sacrificial material may be performed at one or more different stations than employed to deposit the protective layer. In some cases, the temperatures of the individual stations of a multi-station chamber are separately controllable to allow different temperatures for the different operations. Generally, protective layer formatting may be performed at a temperature ranging from about 20° C. to 500° C., and at a pressure ranging from about 10 mTorr to about 100 Torr. The flow rates of reactants in the process can range from about 0.001 sccm to about 10000 sccm (per process chamber housing four 300 mm wafers), and reactant contact times can range from about 0.5 to about 50000 seconds, e.g. from about 0.5 to about 5000 seconds. These process parameters are applicable for gas phase formation of protective layers. Liquid based deposition parameters are presented below.

Protective layers can be formed in any apparatus that provides mechanisms for reagent flow and a process chamber that can effectively isolate the fabricated device from moisture and oxygen of ambient environment. Generally, the apparatus is capable of providing vacuum environment and a temperature that is necessary to perform the protective-forming reaction. For example, various types of CVD tools can be used for protective layer formation. In some embodiments, the protective-forming process may include operations that require plasma treatment, or plasma-enhanced reactions. Therefore, in some embodiments PECVD tools, such as SEQUEL™ and VECTOR™ PECVD tools available from Novellus Systems, Inc. (San Jose, Calif.), may be used. Further, in some embodiments, a dual frequency PECVD apparatus that has high frequency (HF) and low frequency (LF) radio frequency (RF) plasma sources, may be used. Low frequency RF power refers to RF power having a frequency between 100 kHz and 2 MHz. A typical frequency range for LF plasma source is between about 100 kHz to 500 kHz, e.g., 400 kHz frequency may be used. High frequency power refers to RF power with a frequency greater than 2 MHz. Typically HF RF frequency lies in the range of between about 2 MHz-30 MHz. A commonly used HF RF values include 13.56 MHz and 27 MHz. In some embodiments LF power ranging from about 0 W/cm² to 1.0 W/cm², and HF power ranging from 0.1-1.5 W/cm² can be used in plasma assisted operations, such as during pre-clean, pinning and H₂ post-treatment. In some embodiments a single frequency process is used in plasma-assisted operations.

Referring again to FIG. 2, the work piece received during operation 201 is provided to a process chamber may be optionally pre-cleaned as shown by the process block 203. Pre-cleaning operation removes contaminants from the surface of the work piece. In particular, pre-cleaning can remove metal oxide from the metal surface, thereby exposing metal atoms for subsequent reactions. It is desirable to perform pre-cleaning after a CMP operation or any exposure to moisture and oxygen, since CMP can leave a significant amount of contaminants on a work piece surface. Pre-clean operation can be accomplished by, for example, exposing the surface of a work piece to a plasma containing a reducing gas, such as NH₃ or H₂. The experimentation has shown that pre-clean with H₂ plasma has provided devices with particularly improved characteristics. The process gas during pre-clean can also include a carrier gas, such as N₂, He, Ar, etc. In one example, pre-clean is performed in a PECVD chamber at a temperature of about 200-400° C., pressure of about 1.5-4 Torr and an H₂ flow rate of about 4000-10000 sccm. The plasma, which may contain an HF and an LF component is ignited and is sustained at a total power of 200-1000 W per one 300 mm wafer. In some embodiments, HF power at 0.1-1.5 W/cm² and LF power at 0-0.8 W/cm² may be used during the pre-clean operation. In another example, NH₃ is used instead of H₂ as a reducing gas, and is flowed into the process chamber at a flow rate ranging from about 6000 to 8000 sccm. An N₂ carrier gas is flowed into the chamber at a flow rate of about 2000-4000 sccm. The pre-cleaning treatment can last several seconds, e.g., between about 6-20 seconds.

After optional pre-cleaning operation 203, the work piece is contacted with a passivating reagent during an optional passivation operation 205. In some embodiments, the passivating reagent is a nitrogen-containing reagent that is capable of forming metal nitride, e.g., CuₓN_{y} at the surface of the metal layer. In a particular embodiment, the nitrogen-containing reagent is NH₃. Generally, a variety of nitrogen-containing compounds can be used. These include hydrazine (N₂H₂) and amines (e.g., methylamine, ethylamine, diethylamine, etc.). In some embodiments halogens or halogen-containing compounds may be used as passivating agents, partially converting metal surface to metal halides. For example, I₂ can be used. In other embodiments certain hydrocarbons may be used as passivators, partially converting the metal surface to metal carbide. The passivating reagent is generally selected such that it can modify metal surface without the use of plasma. In one embodiment, the passivating reagent is introduced in a controlled fashion, such that the metal surface is not entirely converted to passivated material, but still contains unpassivated metal atoms, which can be converted to a protective material during subsequent protective forming operation. The degree of passivation of the metal surface, can be controlled by parameters of the passivating process, such as nature of the passivating reagent, temperature, flow rate of passivating reagent and contact time of reagent with the metal layer.

In one embodiment, copper surface is partially converted to CuₓN_{y} by flowing NH₃ into a process chamber at a flow rate of about 6000-8000 sccm, at a pressure of about 1.5-4 Torr and at a temperature of about 200° C.-400° C. In this embodiment, plasma is not ignited during the passivation process. In other embodiments, passivation may be plasma-assisted. In some embodiments NH₃ is the only gas that is flowed into the chamber during passivation operation. In other embodiments, NH₃ or other passivating reagent may be diluted by a carrier gas, such as N₂, H₂, He, Ar, etc. The metal layer is contacted with the passivating reagent for a controlled period of time that provides the desired amount of passivated material at the metal surface. For example, the work piece can be treated with NH₃ for about 2-4 seconds to convert a desired fraction of copper surface to copper nitride.

In one embodiment, the passivating operation selectively transforms metal surface without affecting other exposed surfaces of the work piece. For example, passivating operation 205 in this embodiment does not transform the sacrificial material layer and does not deposit any material on a layer of sacrificial material.

Referring again to FIG. 2, the process continues with the formation of a protective layer on the surfaces and/or within the top portion of the metal interconnect lines during operation 207. The work piece may be contacted with one or more precursors to form the protective layer. The one or more precursors react with the available metal atoms of the metal lines but may not affect materials elsewhere on the work piece. For example, the sacrificial material surrounding the metal lines may be substantially inert to the precursors used during this operation. Furthermore, the precursors may not react with the passivated material if one is formed during optional operation 205. Consequently, the depth of the protective layer may correlate with the amount of passivated material formed, such that increased amount of passivated material at the metal surface leads to decreased thickness of the protective layer. As such, the thickness of the protective layer and resistance of interconnect is controlled by the amount of passivated material formed in operation 205, or, rather by the amount of unpassivated metal atoms that remain available for transformation. For example, if all of the metal atoms at the metal surface are converted to passivated material, such as CuₓN_{y}, the protective layer would not form, while if no passivating operation precedes protective-forming operation 207, the first-formed protective layer may be excessively thick, thereby unnecessarily increasing interconnect resistance.

In some embodiments related to gas phase formation of protective layers, one or more precursors used during operation 207 may include a gas or a vapor, selected from the group consisting of SiH₄, GeH₄, PH₃, B₂H₆, AsH₃, an alkane, H₂S, H₂Se, and H₂Te. Further, a variety of metal hydrides and alkylated element hydrides can be used. Examples include SnH₃, SbH₃, and RGeH₃, R₂GeH₂, R₃GeH, wherein R is an alkyl substituent, which can be further substituted with heteroatoms, such as N, P, and S. In some embodiments, metal halides (fluorides, chlorides, bromides or iodides) are used for forming protective layers. For example, in some embodiments, molybdenum halides are used. In these cases, inter-metal compounds and alloys (e.g. CuₓMo_{y}) are formed as protective layers. In general, a variety of metal hydrides and/or halides or alkyl substituted hydrides and/or halides which could be delivered into a CVD chamber in their gaseous forms could be employed as protective forming reactant. Further, in some embodiments, a variety of metal containing compounds (including organometallics) that could be delivered into the CVD chamber in its gaseous form could be used as protective forming reactants. Examples include alkyl, carbonyl, and cyclopentadienyl-substituted organometallic compounds, such as tetrakisdimethylaminotitanium, cyclopentadieneyl molybdenum, nickel tetracarbonyl and iron pentacarbonyl. Typically, such compounds would impregnate top portions of copper lines with thin layers of metals, e.g., Ti, Mo, Ni, Fe and the like to form alloys with copper. Other examples include trimethylaluminum, tetrakis(dimethylamino) titanium(IV) (TDMAT), tetrakis(diethylamino) titanium(IV) (TDEAT), and combinations thereof. Precursors for wet solution formation of protective layers is further described below.

It should be noted that the composition and structure of resulting protective layers should be sufficiently resistant during subsequent etching operations (e.g., have a very low etch rate in the wet chemical etchant) that are used to remove the sacrificial material. For example, if hydrofluoric acid were used to remove the sacrificial material, protective layers that contain silicon nitride, germanium nitride, boron nitride, aluminum nitride, and/or titanium nitride may be used. At the same time, aluminum oxide and silicon oxide that may be useful for some other etchants will generally not be suitable for hydrofluoric acid based etchants.

The precursors (i.e., the protective-forming reactant) contact the semiconductor work piece under such conditions that top portion of the metal is converted to a protective layer. This protective layer may include one or more of the following materials, MₓSi_{y}, MₓGe_{y}, MₓP_{y}, MₓB_{y}, MₓAs_{y}, MₓC_{y}, MₓS_{y}, MₓSe_{y}, and MₓTe_{y}, where M is metal. These materials are formed when SiH₄, GeH₄, PH₃, B₂H₆, AsH₃, an alkane, H₂S, H₂Se, and H₂Te reactants are used. For example, a layer comprising CuₓSi_{y}, CuₓGe_{y}, CuₓP_{y}, CuₓB_{y}, CuₓAs_{y}, CuₓC_{y}, CuₓS_{y}, CuₓSe_{y}, or CuₓTe_{y} may be formed when the metal interconnect lines include copper. In some embodiments, formation of the protective layer is plasma-assisted, e.g., plasma enhanced chemical vapor deposition (PECVD). In other embodiments, including an embodiment in which SiH₄ contacts Cu to form CuₓSi_{y}, plasma may not be ignited during formation of the protective layer. When plasma is not applied, silane selectively reacts with metal surface, without depositing any material on other exposed surfaces of the wafer. For many protective forming reagents plasma should not be ignited during protective layer forming process, in order to achieve selective formation of the protective layer within the exposed surface of the metal interconnect lines, rather than blanket deposition of the material across the entire surface of the work piece. It should be noted that formation of the protective film over the sacrificial material should be generally avoided.

In a particular example, the protective layer is formed by flowing SiH₄ into a process chamber at a flow rate of about 100-1000 sccm. NH₃ at a flow rate of about 4000-10000 sccm or H₂ at a flow rate of about 4000-10000 sccm can be optionally flowed into the process chamber concurrently with silane. The SiH₄ treatment lasts for about 1-6 seconds at a temperature ranging from about 200-400° C. and pressure ranging from about 1.5-4 Torr. In some embodiments, the temperature may be kept below 300° C. in order to limit diffusion of nonconductive species into the metal interconnect lines. In other embodiments, temperatures higher than 300° C. are used, while diffusion of nonconductive species and via resistance are controlled using other methods, e.g., passivation and pinning described elsewhere in this document. No plasma is applied in this embodiment, and SiH₄ selectively reacts only with the metal surface to form a copper silicide containing protective layer.

In certain embodiments, the protective layer is formed by treating the work piece with a surface active reagent that selectively adsorbs on the exposed surfaces of the metal interconnect lines. This embodiment is described in detail in U.S. application Ser. No. 10/980,076, which is incorporated herein by references in its entirety for purposes of describing adsorption of surface active reagents on exposed surfaces of the metal interconnect lines.

Formation of CuₓSi_{y} protective layer will now be explained in more detail. It is understood, that similar considerations may also apply to protective layers with other compositions. When copper surface is contacted with silane at a certain temperature (e.g., between about 200° C.-400° C.), silane catalytically decomposes at copper surface to form elemental silicon, which diffuses into the copper layer and slowly reacts with copper atoms to form CuₓSi_{y}. Copper atoms that initially serve as a catalyst for silane decomposition eventually undergo a transformation to copper silicide, which is the main component of the protective layer. In this scenario, a large amount of elemental silicon is initially formed in operation 207. Passivation of copper layer in operation 205 reduces the fraction of catalytic copper atoms in the zero oxidation state at the exposed surface, and thereby reduces the amount of elemental silicon that is initially formed. Passivation, in certain embodiments, may also play a role in limiting the diffusion of elemental silicon into the copper line. Therefore, passivation reduces the thickness of the protective layer and provides a way to control resistance of protective-containing interconnects.

The following patent documents are incorporated herein by reference in their entireties: U.S. Pat. No. 7,704,873, entitled “PROTECTIVE SELF-ALIGNED BUFFER LAYERS FOR DAMASCENE INTERCONNECTS,” issued on Apr. 27, 2010, Attorney Docket No: NOVLP258US/NVLS-2934C3, U.S. Pat. No. 7,648,899, “INTERFACIAL LAYERS FOR ELECTROMIGRATION RESISTANCE IMPROVEMENT IN DAMASCENE INTERCONNECTS,” issued on Jan. 19, 2010, Attorney Docket No. NOVLP259US/NVLS-3381C1, U.S. Pat. No. 7,858,510, entitled “INTERFACIAL LAYERS FOR ELECTROMIGRATION RESISTANCE IMPROVEMENT IN DAMASCENE INTERCONNECTS,” issued on Dec. 28, 2010, Attorney Docket No. NOVLP259X1US/NVLS-3381CP1, U.S. Pat. No. 7,727,881, entitled “PROTECTIVE SELF-ALIGNED BUFFER LAYERS FOR DAMASCENE INTERCONNECTS,” issued Jun. 1, 2010, Attorney Docket No. NOVLP219US/NVLS-2934C1, U.S. Pat. No. 7,576,006, entitled “PROTECTIVE SELF-ALIGNED BUFFER LAYERS FOR DAMASCENE INTERCONNECTS,” issued on Aug. 18, 2009, Attorney Docket No. NOVLP219AX1US/NOVLP219AX1US, U.S. Pat. No. 7,727,880, entitled “PROTECTIVE SELF-ALIGNED BUFFER LAYERS FOR DAMASCENE INTERCONNECTS,” issued on Jun. 1, 2010, Attorney Docket No. NOVLP219AUS/NVLS-2934C2, US 2010/0308463, entitled “INTERFACIAL CAPPING LAYERS FOR INTERCONNECTS,” published Dec. 9, 2010, Attorney Docket No. NOVLP321US/NVLS-3536.

Another way of selectively forming a protective layer is by exposing the surface of metal interconnect lines to a liquid solution. The solution contains one or more compounds to form a sacrificial self-assembled layer that can inhibit corrosion of the metal interconnect lines during later processing. The one or more compounds may be dissolved in a solvent that is polar or non-polar. The one or more compounds could have a variety of structures containing nitrogen and/or sulfur functional groups including, but not limited, to azoles, amioes, amino acids, thiols, and the like. Some specific examples include benzotriazole, 1-phenyl-1H-tetrazole-5-thiol, 1,3,4-thiadiazole-2,5-dithiol, 3-mercapto-1-propanesulfonic acid, bis-(sodium sulfopropyl)disulfide, and combinations thereof.

In certain embodiments, a work piece may be immersed in a solution containing one or more of these compounds to form a corrosion inhibition layer prior to immersion the work piece into a wet chemical etchant further describe below. In other embodiments, the above recited compounds may be dissolved directly in the wet chemical etching solution. Formation of the protective layer on the metal interconnect lines is performed at the same time as etching the sacrificial material. In either case, a work piece may be exposed to an optical, plasma, thermal, or chemical pre-treatment prior to the formation of the protective layer to remove copper oxide and enable stronger adhesion of the corrosion inhibitor. Various pretreatment techniques are described above with reference to operations 203 and 205.

A non-protective permeable layer may be formed simultaneously with the corresponding protective layer or in a separate operation. In certain embodiments, a non-protective layer is formed after the corresponding protective layer and may coat the protective layer. In other words, an exposed surface of interconnect metal lines may be first coated with a protective layer and then a non-protective layer over the protective layer. This layered structure may provide additional protection to the metal interconnect lines. In other embodiments, patches of the protective layer are positioned adjacent to patches of the non-protective layer (and above the exposed surfaces of the metal interconnect lines). In certain embodiments, there is substantially no overlap between patches of the protective layer and patches of the non-protective layer.

A non-protective permeable layer may be formed by depositing one or more carbon containing materials over a work piece surface. For example, a polymer coating may be used for this purpose. Hydrocarbon bonds may be then broken by exposing this coating to hydrogen plasma (in situ or remote) to turn this polymer into amorphous carbon. Thermal carbonization of the polymers may be used as well. Other methods of depositing amorphous carbon to server as a permeable non-protective layer.

In some embodiments, further diffusion of elemental silicon (or other non-conductive material) into the metal interconnect lines need to be controlled. Diffusion of large amounts of non-conductive material into the metal line leads to unwarranted increase in metal line resistance. An optional “pinning” operation 209 may be used to control such diffusion of elemental silicon. “Pinning” operation forms a sacrificial material cap on or within the protective layer, and serves to limit the diffusion of non-conductive reaction intermediates or by-products into the depth of metal interconnect lines by converting them to a material that does not readily diffuse into the metal. Further, “pinning” operation may transform unstable phases of copper silicide or copper nitride to a more stable material. Even further, “pinning” operation forms a cap of sacrificial material that has good adhesion with sacrificial material diffusion barrier materials. “Pinning operation” is referred to as a “sacrificial material cap” formation in U.S. application Ser. No. 10/980,076, from which the current application claims priority. Further, in certain embodiments, pinning operation may reduce stress migration parameters of formed interconnects. In some methods, multiple cycles of precursor exposure and subsequent pinning are employed to grow a protective layer to a desired thickness. While it is expected that every cycle in a multi-cycle process will include both precursor deposition and pinning, in some implementations, one or more of the cycles is performed without pinning. The number of cycles is chosen to provide a desired thickness of the protective layer. In a typical embodiment, 1 to about 20 cycles of deposition is employed.

Pinned protective layers may be formed by contacting the device work piece with a reactant. In general, pinning can be accomplished by thermal treatment, plasma treatment, chemical treatment, or some combination of the three. In one embodiment, pinning is performed by contacting the work piece containing the protective layers with a pinning reagent selected from the group consisting of N₂, NH₃, a hydrocarbon, a gas from the family of methyl-substituted amines, and mixtures thereof. In some embodiments silicon-containing pinning reagents, such as a gas from the family of methyl-substituted silanes or HMDS may be used. Generally, modification of the protective layer with the pinning reagent is performed with plasma treatment. In one embodiment, the protective layer containing CuₓSi_{y} is treated with NH₃ in a plasma. Under conditions practiced in this embodiment, excess of elemental silicon residing within and/or on the surface of metal line is transformed into silicon nitride, which does not readily diffuse into the bulk of metal layer. Further, under conditions of such pinning, CuₓSi_{y} is partially or completely transformed to copper metal (at zero oxidation state) impregnated with silicon nitride, thereby forming an excellent adhesive layer at the interface of metal fill and a sacrificial material diffusion barrier.

In a particular example, a work piece having a CuₓSi_{y} protective layer is treated with NH₃ and N₂ in a plasma generated using HF and LF power sources. NH₃ is introduced into a process chamber at a flow rate of about 6000-8000 sccm. N₂ is flowed into the chamber at a flow rate of about 2000-4000 sccm. The work piece is treated at a temperature of about 200-400° C., and pressure of about 1.5-4 Torr for a period of time ranging from about 3 to 20 seconds. Plasma is ignited using HF and LF power sources at a total power level of about 200-1000 W for one 300 mm wafer. As a result, a pinned protective layer containing SiₓN_{y} is formed.

Note that in some embodiments the same reagent may be used during the passivation operation 205 and a pinning operation 209. For example, in some embodiments, NH₃ is used as a passivating reagent without use of plasma and as a pinning reagent in a plasma-enhanced process. Further, in some embodiments, NH₃ is also used in the pre-cleaning step and as an auxiliary gas during formation of the protective layer.

In some embodiments, (including embodiments employing hydrocarbon and silicon containing pinning reagents) pinning conditions are generally selected such that only the protective layer is transformed, while no substantial deposition occurs elsewhere on the work piece, e.g., on a sacrificial material field. Generally, in these embodiments no more than 10 Å of material is deposited elsewhere on the sacrificial material field regions of the work piece.

Depending on a reagent that is used in pinning, the pinned protective layer may contain SiₓN_{y}, SiₓC_{y}, hydrogen-doped carbon or a combination of these materials. For example, treatment with hydrocarbons will result in SiₓC_{y} or C:H-containing pinned protective layer, while treatment with NH₃ and N₂ will result in SiₓN_{y} containing pinned protective layer. In certain embodiments, pinning may transform an entire protective layer to a pinned layer having a different composition. In other embodiments, pinning may result in a layer that is higher than the layer of surrounding sacrificial material. For example, if substantial amount of elemental silicon formed on the surface of metal layer is transformed to silicon nitride, the pinned protective layer (or a sacrificial material cap) may be higher than the level of surrounding sacrificial material. In some embodiments, the entire protective layer is transformed to a pinned protective layer. For example, all of the copper silicide of the protective layer may be converted to silicon nitride. In other embodiments, certain amounts of material of the protective layer may not be transformed during pinning. For example, certain particularly stable phases of copper silicide may remain in the pinned protective layer. Yet, in other embodiments, only the top portion of the protective layer may be transformed by pinning (partially or completely), thereby forming a bi-layer structure. For example, the pinned protective layer may have a bottom layer that contains copper silicide, and a top layer that contains silicon nitride. Typically concentrations of components gradually change within the protective layers, thereby providing for good adhesion between metal and a sacrificial material.

In some cases, pinning using hydrocarbons was found to be associated with improvement in stress migration parameters of interconnects. Hydrocarbons, as used herein, are defined as compounds with CₓH_{y} composition, which may be optionally substituted with heteroatoms, such as S, N, P, etc. Hydrocarbons, as used herein include acyclic and cyclic alkanes, alkenes, alkynes, as well as amines, mercaptans, thioethers and phosphines. Examples of hydrocarbons that do not include heteroatoms and that can be used as pinning reactants are methane, ethane, ethylene, acetylene, propane, propene, propyne, cyclopropane, cyclobutane, butanes, butenes, butynes, and benzene.

In some embodiments, pinning is performed exclusively with hydrocarbons in a plasma without NH₃, N₂ and other pinning reagents. In other embodiments, mixtures of pinning reagents (e.g., NH₃, N₂,) with a hydrocarbon may be used during plasma-assisted pinning. Hydrocarbon content in the process gas can range from about 0.0001% (trace values) to 100%, generally from about 1% to 100% by volume. Pressure, temperature, and plasma conditions for hydrocarbon pinning can be similar to those described above for NH₃ pinning. In one embodiment the protective layer is treated with a mixture of NH₃ (or N₂) flowed into the process chamber at the flow rate range of between about 500 sccm to 5000 sccm and cyclopropane flowed in the range of 2.5 sccm to 5000 sccm per one 300 mm wafer using a plasma. When such treatment is performed on CuₓSi_{y} protective layer containing a SiₓC_{y}N_{z} material is typically formed.

In another embodiment a hydrocarbon is flowed into the process chamber without being mixed with other pinning reagents. For example, cyclopropane can be flowed into the chamber at a flow rate ranging from about 2.5 to 5000 sccm per one 300 mm wafer. The plasma is then ignited under similar conditions or under slightly modified conditions, as described for NH₃ pinning and the protective layer is modified by hydrocarbon pinning. When such treatment is performed on CuₓSi_{y} protective layer containing a SiₓC_{y} material is typically formed.

It was also found that treatment of protective layers with H₂ plasma during or after pinning improves stress migration characteristics of interconnects. H₂ plasma chemically modifies the surface of the protective layer and leads to structures with lower stress migration, presumably also by slowing the migration of vacancies within the via. In some embodiments H₂ is included into the process gas used during pinning Examples of mixtures of pinning reagents with H₂, which can be used include: NH₃ and H₂; N₂ and H₂; NH₃, N₂, and H₂; hydrocarbon, NH₃, and H₂; hydrocarbon, N₂, and H₂. In one embodiment, H₂ plasma treatment is used instead of pinning (no other pinning reagents added). Other combinations of pinning reagents (e.g., ternary mixtures) with hydrogen may be used, as will be understood by those of skill in the art. H₂ can be supplied into the process chamber at a flow rate ranging from 40 to 20000 sccm per four 300 mm wafers or 10 to 5000 sccm per one 300 mm wafer. In some embodiments H₂ comprises at least 0.01% of the total gas flow during pinning, generally between 1 and 50%. Plasma, temperature, and pressure conditions for pinning which includes H₂, can be similar to those listed for NH₃ pinning.

In some embodiments, H₂ plasma treatment is performed after the pinning operation is completed, as shown by process block 211. During H₂ plasma post-treatment, H₂ can be supplied to the process chamber either alone or concurrently with inert carrier gas at a flow rate ranging from about 40 to 20000 sccm per four 300 mm wafers or 10 to 5000 sccm per one 300 mm wafer. Plasma, temperature, and pressure conditions for H₂ post-treatment can be similar to those listed above for NH₃ pinning operation.

### Removal of Sacrificial Material

Once protective layers are formed and optionally pinned or otherwise processed in accordance with various embodiments described above, the sacrificial material is selectively removed from the interconnect layer during operation 213. This operation may involve ashing or etching, e.g., exposing the work piece to an etchant that reacts with the sacrificial material and removes at least a portion of this material. In other embodiments, a wet etch is employed to remove the sacrificial material. For example, a wet etching method includes using an HF solution or vapor HF. For smaller size lines, removal by vapor-type etchant or plasma etching may be used to ensure that there is no residue inside the air gap. During these operations, the protective layer protects the surfaces of the metal interconnect lines from substantial etching, wherein exposing the work piece to the etchant defines at least a portion of the air gap.

Some of the examples will now be described in more details. In certain embodiments, wet etching is used to remove sacrificial materials from a work piece by contacting the work piece with etchant. The contact may involve immersing the work piece in a bath of etchant, spraying etchant on the work piece, condensing etchant on the work piece, etc. The bath may have a specific composition, may be kept at specific temperature, and may be agitated to achieve good process control. For example, a buffered hydrofluoric acid solution may be used to etch when sacrificial materials include silicon dioxide. This solution may include a mixture of a buffering agent, such as ammonium fluoride (NH4F) and hydrofluoric acid (HF). Ammonium fluoride is used to improve process control as concentrated hydrofluoric acid generally etches silicon dioxide too quickly. To deal with insoluble products created by hydrofluoric acid etching, hydrochloric acid may be added to the solution as well. In certain embodiments, a solution includes include a water based solution of ammonium fluoride having the ammonium fluoride content of between about 30% and 50%, for example, about 40%. The solution also includes a water based solution of hydrofluoric acid having the hydrofluoric acid content of between about 40% and 60%, for example, about 50%. A volumetric ratio of the ammonium fluoride solution to the hydrofluoric acid solution may be between about 10:1 and 3:1, for example, 6:1. Such solutions may etch silicon oxide sacrificial materials at rates of between about 0.5 nanometers per second to about 10 nanometers per second at the room temperature. The temperature can be increased to raise the etching rate. Continuous stirring of the solution during etching process helps to have homogeneous solution which may etch uniformly by removing etched material from the surface.

Another example of sacrificial material removal is plasma etching. Plasma etchers can operate in several modes by adjusting the parameters of the plasma and other process conditions. In certain embodiments, the chamber for performing plasma etching is maintained at a pressure of between about 0.1 and 5 Torr. In some implementations, the plasma produces energetic free radicals, neutrally charged, that react at the surface of the work piece. Since neutral particles attack the surface of the work piece from all angles, this process is generally isotropic. Plasma etching can be isotropic, i.e., exhibiting a lateral undercut rate on a patterned surface approximately the same as its downward etch rate, or can be anisotropic, i.e., exhibiting a smaller lateral undercut rate than its downward etch rate. Such anisotropy is maximized in reactive ion etching. In some embodiments, the source gas for the plasma contains small molecules rich in chlorine or fluorine. For instance, chlorine (Cl₂), dichlorodifluoromethane (CCl₂F₂), trifluoromethane (CHF₃), tetrafluoromethane (CF₄), sulfur hexafluoride (SF₆), and nitrogen trifluoride (NF₃), may be used for etching silicon dioxide using this techniques. When polymers are used as sacrificial material, these polymers may be removed by ashing, i.e., using oxygen containing etchants. For nitride based sacrificial materials, phosphoric acid may be used.

Yet another example includes sputter etching, which may be performed at even lower pressure levels than plasma etching. Sputter etching involves bombards the work piece with energetic ions of noble gases, often Ar+, which knock atoms from the work piece by transferring momentum. Because the etching is performed by ions, which approach the surface of the work piece approximately from one direction, this process is generally highly anisotropic. On the other hand, it tends to display poor selectivity and require robust protective layers. Reactive-ion etching operates is yet another example of suitable etching techniques.

In certain embodiments, all sacrificial material is removed at least from the top layer of the IC stack. In other embodiments, removal operation is controlled to provide only partial removal of the sacrificial material. The remaining part of the sacrificial material is retained and becomes a part of the final IC. In these later embodiments, the air gap formed after the removal operation may only extend to part of the layer thickness (that corresponds to vias' and trenches' depth). This approach may be used to fine tune the reliability by controlling the removal operation and retaining a controlled amount of the sacrificial amount in between the metal interconnect lines. Various etch chemistries and conditions may be employed to partially remove the sacrificial dielectric. In some cases, a conventional wet etch process is employed for oxide dielectric removal. In some cases, a dry etch is employed to completely or partially remove the sacrificial dielectric.

It should be noted that that protective layers used over exposed surfaces of the metal interconnect lines should be sufficient resistant to etchant and etching conditions described above and prevent any or substantial interaction between the etchants and metal of the interconnect lines. At the same time, non-protective permeable layers, if such layers are used, during processing should be permeable to etchants and etching products.

### Partially Filling Voids—Non-Conformal Layer Deposition

Process 200 may proceed with partially filling voids during operation 215. This operation may be used to seal the voids and provide the surface for forming another level of the integrated circuit. Some air gaps are retained in between the metal interconnect lines after this operation. This partial filling may be accomplished by non-conformal deposition of one or more dielectric materials. In certain embodiments, these dielectric materials may be the same as sacrificial materials which have been removed to form the voids. In other embodiments, the materials are different. For example, an initial sacrificial material may be selected to allow easy removal. A material used to partially fill voids may have low dielectric constants and allow for specific deposition profiles (non-conformal or conformal). Some examples of these later deposited materials include silicon carbides and boron nitrides. In certain embodiments, the later deposited materials may have a layered structure with an inner layer having a higher nitrogen concentration and outer layer having a higher oxygen concentration. This material also serve as a diffusion barrier layer. It should be noted that metal barrier layers provided on sides of metal interconnect lines may be thinner in integrated circuits having air gaps than in circuits where all space between metal lines because in the former approach the concern with electromigration is substantially less. Thinning the diffusion barrier layers provides more space for conductive lines and may be used to improve conductivity of the integrated circuit.

Non-conformal coating may be achieved by controlling various process parameters, such as precursor flow rates, temperatures, RF power, and the like. In certain embodiments, the process conditions are tailored such that deposition of the new material is performed in a mass transport regime, where concentration of precursor molecules is higher near the opening of the voids than inside the voids. Some examples of techniques for depositing non-conformal layers include PECVD deposition of dielectric materials such as SiO₂, SIN, SiCN, SiCOH films.

### Examples of Structures

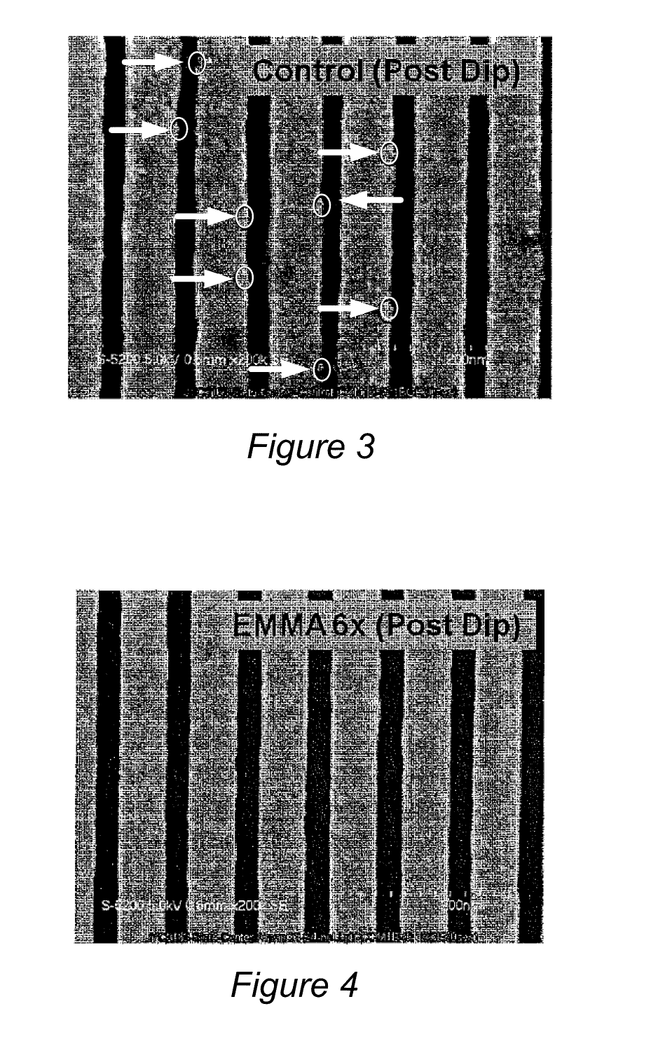

FIGS. 3 and 4 illustrate SEM images of two samples after wet etching operation in hydrofluoric acid solutions. FIG. 3 corresponds to a sample that was etched without any protective layers deposited over copper interconnect lines, while FIG. 4 corresponds to a sample that was etched with a protective layer selectively deposited over the copper interconnect lines. In the depicted example, the copper interconnect lines had a line/spacing of 60/30 nm. The dielectric between the lines was silicon oxide. A standard BOE wet etch process was used to remove the oxide and to permit observation of the impact of the protective layer on copper lines during the wet etch process. FIG. 3 shows various imperfections on the sides of the copper lines (identified with circles and arrow). Such defects are generally absent in the structure illustrated in FIG. 4. In this example, the defects occur on the side surfaces of the copper lines. In practical implementations, the protective layer typically will be used to protect the top surfaces of the metal lines and not the sidewall since the sidewall may be covered by the dielectric between the metal lines. If there is dishing of the dielectric during chemical mechanical polishing, then the top portion of the sidewall which will be exposed to copper capping process will also be coated with the protective layer.

### Apparatus

The techniques described above can be implemented in many different types of apparatus or more generally processing systems, such as chemical vapor deposition (CVD) reactors and spin-coating systems. Generally, the apparatus will include one or more chambers or “reactors” (sometimes including multiple stations) that house one or more work pieces and are suitable for processing. Each chamber may house one or more work pieces for processing. The one or more chambers maintain the work piece in a defined position or positions (with or without motion within that position, e.g. rotation, vibration, or other agitation). In one embodiment, a work piece undergoing the protective layer and/or non-protective layer deposition is transferred from one station to another within the processing system during the process. While in process, each work piece is held in place by a pedestal, chuck and/or other work piece holding apparatus. For certain operations, in which the work piece is to be heated, the apparatus may include a heater such as a heating plate. For example, a PECVD system may be used. In some embodiments, the PECVD system includes a LF RF power source.

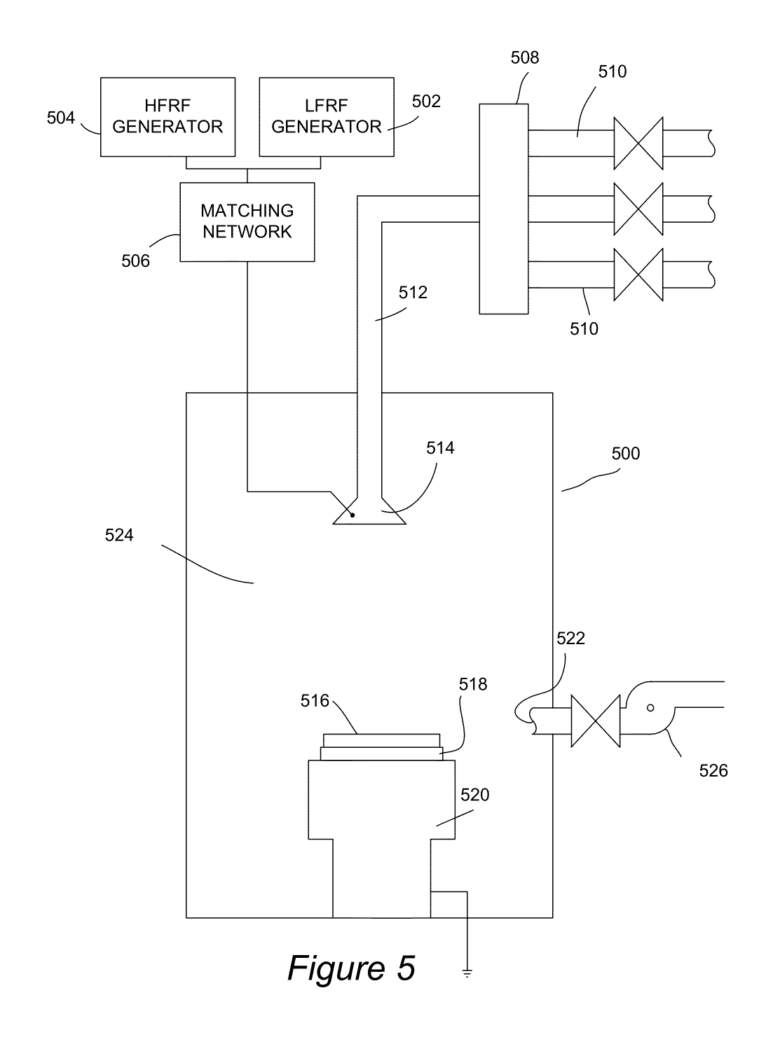

FIG. 5 provides a simple block diagram depicting various reactor components arranged for performing various operations of creating an air gap in an interconnect layer, in accordance with certain embodiments. As shown, a reactor 500 includes a process chamber 524, which encloses other components of the reactor and serves to contain the plasma generated by a capacitor type system including a showerhead 514 working in conjunction with a grounded heater block 520. A high-frequency RF generator 502 and a low-frequency RF generator 504 are connected to a matching network 506 that, in turn is connected to showerhead 514.

Within the reactor, a pedestal 518 supports a work piece 516. The pedestal typically includes a chuck, a fork, or lift pins to hold and transfer the work piece during and between the deposition reactions. The chuck may be an electrostatic chuck, a mechanical chuck or various other types of chuck as are available for use in the industry and/or research.

The process gases are introduced via inlet 512. Multiple source gas lines 510 are connected to manifold 508. The gases may be premixed or not. Appropriate valving and mass flow control mechanisms are employed to ensure that the correct gases are delivered during the pre-cleaning, passivation, protective formation and pinning phases of the process. In case the chemical precursor(s) is delivered in the liquid form, liquid flow control mechanisms are employed. The liquid is then vaporized and mixed with other process gases during its transportation in a manifold heated above its vaporization point before reaching the deposition chamber.

Process gases exit chamber 500 via an outlet 522. A vacuum pump 526 (e.g., a one or two stage mechanical dry pump and/or a turbo-molecular pump) typically draws process gases out and maintains a suitably low pressure within the reactor by a close loop controlled flow restriction device, such as a throttle valve or a pendulum valve.

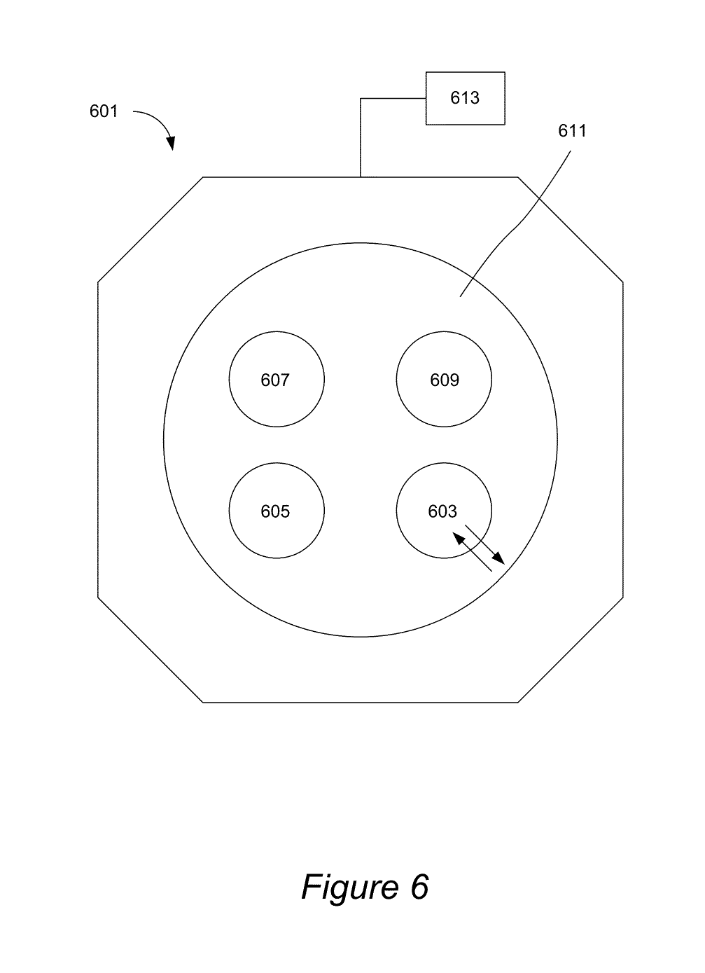

In one of the embodiments a multi-station apparatus may be used for forming a protective layer and a non-protective barrier or to form a protective layer and to remove sacrificial material. The multi-station reactor allows one to run different processes concurrently in one chamber environment, thereby increasing the efficiency of work piece processing. One example of such an apparatus is depicted in FIG. 6. A schematic presentation of top view is shown. An apparatus chamber 601 comprises four stations 603-609. In general, any number of stations is possible within the single chamber of a multi-station apparatus. Station 603 is used for loading and unloading of the work pieces. An indexing plane 611 is used to index work pieces from station to station. A system controller 613 can comprise instructions for the processes described herein. Stations 603-609 may have the same or different functions. For example, some of the stations may be devoted to protective forming operation, while other stations may be used for depositing the dielectric non-protective film and/or to perform etching operations o remove the sacrificial material.

In one of the embodiments, individual stations can operate under distinct process conditions and may be substantially isolated from each other. For example one station may operate under one temperature regime, while another may operate under a different temperature regime. In one embodiment, pre-cleaning operation, protective layer formation process and/or etching are performed in one preferred temperature regime and are carried out in one station of the multi-station apparatus. Some operations may require a different temperature regime (e.g., a higher temperature), and may be carried out in a different station or stations. In other embodiments, etching is performed under the same temperature regime as the protective layer formation and at the same station that performs protective formation. In some embodiments, a protective layer is formed at one station, and the work piece is then indexed to a different station where etching is performed using different processing conditions. In some embodiments, the capping protective layer is formed at one station, while an encapsulating protective layer is formed at a different station under a different temperature regime.

In some embodiments, the entire protective-forming process including pre-treatment, passivation, protective layer formation, pinning, and H2 plasma post-treatment is performed in one station of a single station or a multi-station apparatus. In some embodiments, deposition of a dielectric diffusion barrier layer may be also performed at the same station as protective layer formation.

In one embodiment, station 605 may be devoted to pre-clean and to formation of the protective layer. Station 605 may operate at a temperature range of about 200-300° C. The work piece is then indexed to station 607, where an etching operation is performed under a different temperature regime, e.g., at a temperature range of about 200-400° C.

The process conditions and the process flow itself can be controlled by a system controller 613 which comprises program instructions for a monitoring, maintaining and/or adjusting certain process variables, such as HF and LF power, gas flow rates and times, temperature, pressure and the like. For example, instructions specifying flow rates of silane and/or germane for protective layer deposition may be included. The instructions may specify some or all of the parameters to perform operations, according to methods described above. For example, instructions may include parameters of pre-clean, passivation, protective layer formation, non-protective layer, pinning operations, other post-deposition treatments, etching, partial filling, and the like. The controller may comprise different or identical instructions for different apparatus stations, thus allowing the apparatus stations to operate either independently or synchronously.

The system controller will typically include one or more memory devices and one or more processors. The processor may include a central processing unit (CPU) or computer, analog and/or digital input/output connections, stepper motor controller boards, and other like components. Instructions for implementing appropriate control operations are executed on the processor. These instructions may be stored on the memory devices associated with the controller or they may be provided over a network.

In certain embodiments, the system controller controls all or most activities of the semiconductor processing system described herein. For example, the system controller may control all or most activities of the semiconductor processing system associated with depositing protective layers and removing sacrificial materials. The system controller executes system control software including sets of instructions for controlling the timing of the processing steps, pressure levels, gas flow rates, and other parameters of particular operations further described below. Other computer programs, scripts, or routines stored on memory devices associated with the controller may be employed in some embodiments.

Typically, there is a user interface associated with the system controller. The user interface may include a display screen, graphical software to display process conditions, and user input devices such as pointing devices, keyboards, touch screens, microphones, and other like components.

The computer program code for controlling the above operations can be written in any conventional computer readable programming language: for example, assembly language, C, C++, Pascal, Fortran, or others. Compiled object code or script is executed by the processor to perform the tasks identified in the program.

Signals for monitoring the process may be provided by analog and/or digital input connections of the system controller. The signals for controlling the process are output on the analog and digital output connections of the processing system.

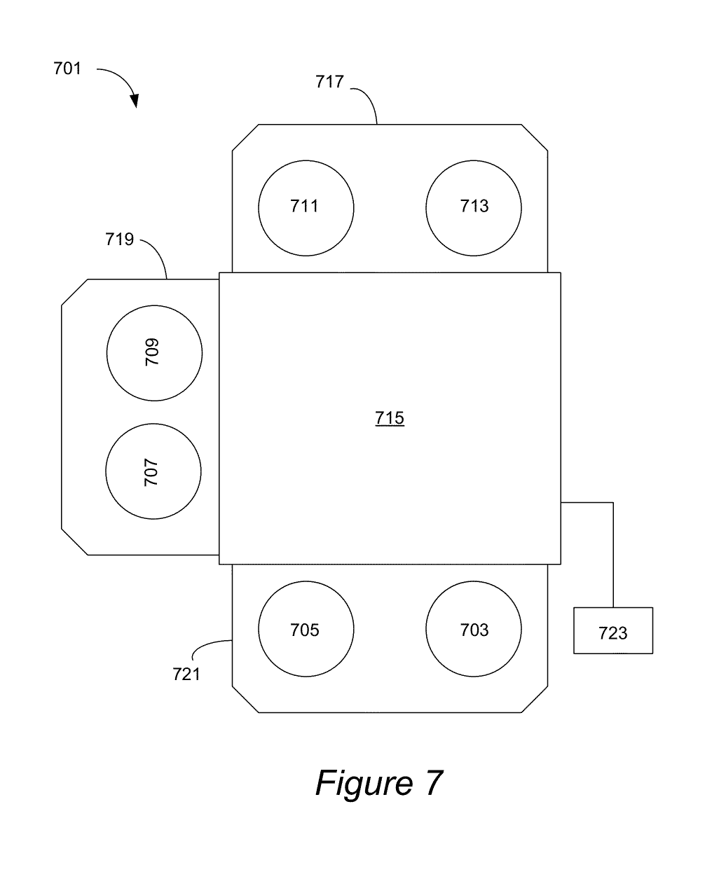

Another example of a multi-station apparatus is illustrated in FIG. 7. However, thing multi-station apparatus 701 includes six stations 703, 705, 707, 709, 711, and 713 residing in three separate processing chambers 717, 719, and 721, with two stations residing in each chamber, and, therefore, may be referred to as a multi-chamber apparatus. A robot-containing chamber 715 adjacent chambers 717, 719, and 721 provides mechanism for loading and unloading the work pieces into the stations. A system controller 723 provides instructions for operation of a multi-station apparatus 701. Individual stations within one chamber are isolatable from each other and may carry out identical or different operations. In one embodiment, two work pieces are simultaneously transferred to stations 703 and 705 residing in one chamber 721 and simultaneously undergo identical operations including pre-clean, passivation, protective layer formation and/or pinning. After this process is completed, the two work pieces are removed from the chamber 721, and are simultaneously introduced to stations 707 and 709 residing in chamber 709. In this chamber, etching of sacrificial materials may be performed. The work pieces are then removed from chamber 719, and are introduced to stations 711 and 713 residing in chamber 717, where further processing, such as partial filling of voids, follows. In some embodiments, formation of protective and/or non-protective layer may be performed in a multi-chamber apparatus with different sub-processes performed in different chambers. In some embodiments, at least two operations of the protective and/or non-protective layer forming process are performed in different chambers of a multi-chamber apparatus. For example, protective layer can be formed in one chamber under a first temperature regime, while non-protective layer may be formed in a different chamber under a different temperature regime.

There is a variety of ways, in which the protective layer forming process can be implemented in multi-station tools, such as those shown in FIG. 6 and FIG. 7. In general, the described protective process is easily integrated into the Damascene flow, does not require substantial resource-consuming handling of work pieces, and can be performed in the same apparatus as other operations.

### Additional Embodiments

The apparatus/process described hereinabove may be used in conjunction with lithographic patterning tools or processes (for example, for the fabrication or manufacture of semiconductor devices, displays, LEDs, photovoltaic panels and the like). Typically, though not necessarily, such tools/processes will be used or conducted together in a common fabrication facility. Lithographic patterning of a film typically includes some or all of the following steps, with each step enabled with a number of possible tools: (1) application of photoresist on a work piece (i.e., substrate, using a spin-on or spray-on tool); (2) curing of photoresist using a hot plate or furnace or UV curing tool; (3) exposing the photoresist to visible, UV, or x-ray light with a tool such as a wafer stepper; (4) developing the resist so as to selectively remove resist and thereby pattern it using a tool such as a wet bench; (5) transferring the resist pattern into an underlying film or work piece by using a dry or plasma-assisted etching tool; and (6) removing the resist using a tool such as an RF or microwave plasma resist stripper.

### CONCLUSION

Although the foregoing concepts have been described in some detail for purposes of clarity of understanding, it will be apparent that certain changes and modifications may be practiced within the scope of the appended claims. It should be noted that there are many alternative ways of implementing the processes, systems, and apparatuses. Accordingly, the present embodiments are to be considered as illustrative and not restrictive.

What is claimed is:

1. A method of creating an air gap in an interconnect layer, the method comprising:
(a) receiving a work piece having an interconnect layer comprising metal interconnect lines having exposed surfaces and a sacrificial material around a portion of the metal interconnect lines not including the exposed surfaces of the metal interconnect lines;
(b) selectively forming a protective layer on the exposed surfaces of the metal interconnect lines, wherein the protective layer is formed from one or more precursor gases in a reaction chamber; and
(c) exposing the work piece to an etchant to selectively remove the sacrificial material from the interconnect layer, while the protective layer protects the surfaces of the metal interconnect lines from substantial etching, wherein exposing the work piece to the etchant defines at least a portion of the air gap.

2. The method of claim 1, wherein exposing the work piece to the etchant exposes, at least partially, sidewalls of the metal interconnect lines.

3. The method of claim 1, wherein the etchant comprises one or more materials selected from the group consisting of ammonium fluoride and hydrofluoric acid.

4. The method of claim 1, wherein the etchant comprises one or more materials selected from the group consisting of chlorine, dichlorodifluoromethane, trifluoromethane, tetrafluoromethane, sulfur hexafluoride, and nitrogen trifluoride.

5. The method of claim 1, further comprising (d) forming a dielectric layer over the exposed surfaces of the metal interconnect lines.

6. The method of claim 5, wherein forming the dielectric layer over the surfaces of the metal interconnect lines comprises performing non-conformal chemical vapor deposition (CVD).

7. The method of claim 6, wherein performing non-conformal chemical vapor deposition (CVD) creates closed voids in the dielectric layer in between the metal interconnect lines.

8. The method of claim 7, wherein the closed voids occupy at least about 25% of the volume of the interconnect layer.

9. The method of claim 1, wherein the one or more precursor gases used for selectively forming the protective layer are selected from the group consisting of silane, germane, diborane, trimethylaluminum, tetrakis(dimethylamino) titanium, and tetrakis(diethylamino)titanium.

10. The method of claim 1, further comprising forming a semipermeable layer over the interconnect layer and wherein exposing the work piece to the etchant removes the sacrificial material under the semipermeable layer and thereby form the air gaps.

11. The method of claim 10, wherein the semipermeable layer extends over the protective layer.

12. The method of claim 10, wherein the semipermeable layer formed from the one or more precursor gases in the reaction chamber used to form the protective layer, and wherein patches of the semipermeable layer are formed in between patches of the protective layer.

13. The method of claim 10, wherein the semipermeable layer comprises a polymer.

14. The method of claim 1, wherein the sacrificial material comprises a silicon oxide.

15. The method of claim 1, further comprising, prior to selectively forming the protective layer, pre-cleaning the received work piece to removes contaminants from at least the exposed surfaces of the metal interconnect lines.

16. The method of claim 15, wherein pre-cleaning the received work comprises plasma treatment.

17. The method of claim 1, wherein selectively forming comprises depositing the protective layer on the exposed surfaces of the metal interconnect lines without substantially depositing the protective layer over the sacrificial material.

18. The method of claim 1, wherein the metal interconnect lines comprise a metal fill within a damascene region of the partially fabricated semiconductor device.

19. The method of claim 1, wherein the metal lines comprise copper.

20. The method of claim 1, wherein the protective layer has a thickness of at least about 100 Å.

21. The method of claim 1, wherein selectively forming the protective layer comprises flowing the one or more precursor gases at a flow rate from about 0.001 sccm to about 10,000 sccm, maintaining the work piece at a temperature of between about 20° C. to about 500° C., and maintaining the reaction chamber at a pressure of between about 10 mTorr to about 100 Torr.

22. The method of claim 1, wherein the method is performed in a multi-station apparatus.

23. The method of claim 1, wherein the method is performed in a multi-chamber apparatus.

24. The method of claim 1, wherein at least two operations are performed in two different stations of a multi-station apparatus.

25. The method of claim 1, wherein at least two operations are performed in two different chambers of a multi-chamber apparatus.

26. A processing system for creating an air gap in an interconnect layer, the processing system comprising:
a reaction chamber for receiving a work piece having an interconnect layer comprising metal interconnect lines having exposed surfaces and a sacrificial material around a portion of the metal interconnect lines not including the exposed surfaces of the metal interconnect lines; and
a system controller comprising a set of instructions for performing the following operations:
introducing one or more precursor gases in the reaction chamber to selectively form a protective layer on the exposed surfaces of the metal interconnect lines; and
exposing the work piece to an etchant to selectively remove the sacrificial material from the interconnect layer, while the protective layer protects the surfaces of the metal interconnect lines from substantial etching, wherein exposing the work piece to the etchant defines at least a portion of the air gap.

27. The processing system of claim 26, wherein the reaction chamber is a multistation chamber.

28. The processing system of claim 27, further comprising a stepper.
